(19) United States
(12) Patent Application Publication
(10) Pub. No.: US 2026/0186044 A1
(43) Pub. Date: Jul. 2, 2026

(54) SEMICONDUCTOR TESTING DEVICE

(71) Applicant: KABUSHIKI KAISHA NIHON MICRONICS, Tokyo (JP)

(72) Inventors: Hideki IKEUCHI, Tokyo (JP); Furawa ODAGIRI, Tokyo (JP); Shoujirou YAHATA, Tokyo (JP)

(73) Assignee: KABUSHIKI KAISHA NIHON MICRONICS, Tokyo (JP)

(21) Appl. No.: 19/408,199

(22) Filed: Dec. 3, 2025

(30) Foreign Application Priority Data
Dec. 26, 2024 (JP) 2024-230498

(51) Int. Cl. G01R 31/28

(52) U.S. Cl. CPC G01R 31/2831

(57) ABSTRACT

A tester includes a performance board unit on which a device under test for testing a semiconductor circuit is mounted, a plurality of board units electrically connected to the device under test via the performance board unit, and a main body unit having an accommodating portion in which the plurality of board units are accommodated, in which the performance board unit is detachably attached to the main body unit with an opening of the accommodating portion closed.

### BACKGROUND OF THE INVENTION

### Field of the Invention

The present invention relates to a semiconductor testing device.

Priority is claimed on Japanese Patent Application No. 2024-230498, filed on December 26, 2024, the content of which is incorporated herein by reference.

### Description of Related Art

Patent Document 1 (Japanese Unexamined Patent Application, First Publication No. 2004-172551) discloses a wafer test system that performs electrical inspection of a plurality of semiconductor chips (dies) formed on a semiconductor wafer. This wafer test system includes a prober that brings a probe into contact with an electrode of a semiconductor chip formed on a wafer, and a tester that has a terminal electrically connected to the probe, operates the semiconductor chip via the terminal, and inspects electrical characteristics of the semiconductor chip by detecting an output signal thereof.

This tester (semiconductor testing device) includes a tester main body, a test head, and a cable connecting the tester main body and the test head.

The test head includes a probe card (device under test) and a performance board (signal transmission unit) electrically connected to a terminal of the probe card. The tester main body includes a board unit that exchanges signals with the test head via the cable, and a power unit that supplies power to the board unit.

### SUMMARY OF THE INVENTION

The tester described above has a configuration in which the tester main body and the test head are connected via the cable, but in recent years, there has been a demand for a compact tester in which the tester main body and the test head (performance board) are integrated. Since such a tester houses the above-described units in a single housing, it has been difficult to replace the performance board or substitute the board unit according to specifications of a semiconductor chip, and there has been room for improvement in customizability.

The present invention has been made in view of the above-described problems, and an objective thereof is to provide a compact semiconductor testing device with high customizability.

A semiconductor testing device according to one aspect of the present invention includes a signal transmission unit on which a device under test for testing a semiconductor circuit is mounted, a plurality of board units electrically connected to the device under test via the signal transmission unit, and a main body unit having an accommodating portion in which the plurality of board units are accommodated, in which the signal transmission unit is detachably attached to the main body unit with an opening of the accommodating portion closed.

According to the above-described aspect of the present invention, it is possible to provide a compact semiconductor testing device with high customizability.

### BRIEF DESCRIPTION OF THE DRAWINGS

FIG. 1 is a schematic view of an inspection system including a tester according to a first embodiment.

FIG. 2 is a perspective view of the tester according to the first embodiment.

FIG. 3 is an exploded perspective view of the tester according to the first embodiment.

FIG. 4 is an exploded perspective view of a performance board unit according to the first embodiment.

FIG. 5 is a plan view of an underbase unit according to the first embodiment with a cover member removed.

FIG. 6A is a view along the arrow VI in FIG. 5 showing a released position of connectors.

FIG. 6B is a view along the arrow VI in FIG. 5 showing a fixed position of connectors.

FIG. 7 is an enlarged view of region A illustrated in FIG. 5.

FIG. 8 is a perspective view of a tester according to a second embodiment.

FIG. 9 is an exploded perspective view of the tester according to the second embodiment.

FIG. 10 is a plan view of an underbase unit according to the second embodiment.

FIG. 11 is an enlarged view of region B illustrated in FIG. 10.

### DETAILED DESCRIPTION OF THE INVENTION

Hereinafter, embodiments of the present invention will be described on the basis of the drawings.

The embodiments described below are intended to exemplify apparatuses and methods for embodying the technical ideas of this invention, and the embodiments of the invention are not intended to limit materials, shapes, structures, arrangements, and the like of the components to those described below.

### First embodiment

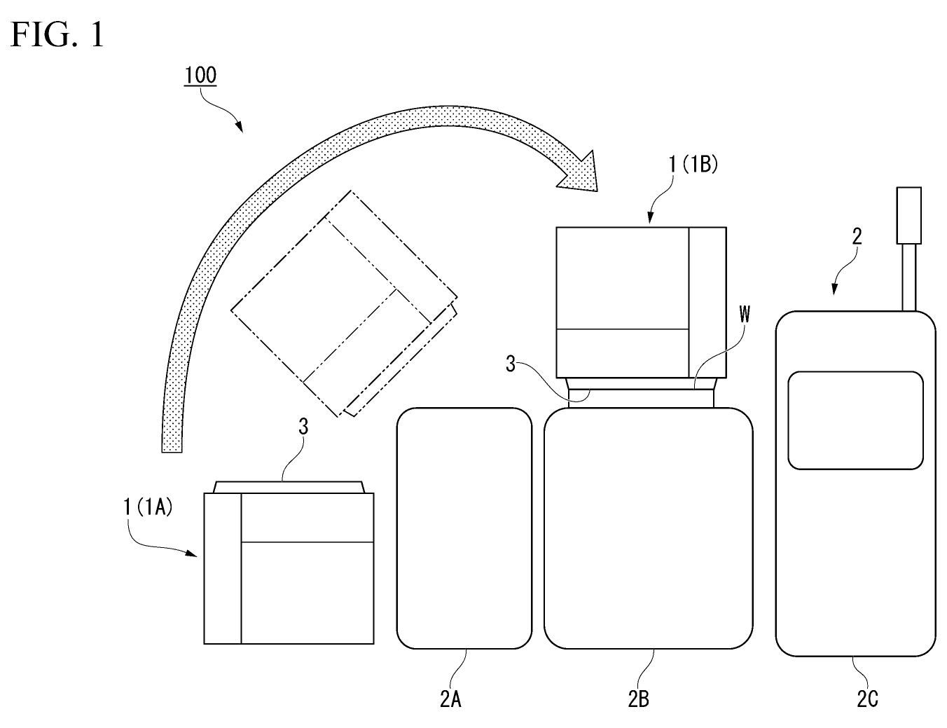

FIG. 1 is a schematic view of an inspection system 100 including a tester 1 according to a first embodiment. The inspection system 100 illustrated in FIG. 1 includes the tester 1 (semiconductor testing device) and a prober 2. The inspection system 100 inspects electrical characteristics of respective semiconductor circuits before a plurality of semiconductor circuits formed on a wafer W are individually diced into chips.

A probe card 3 (device under test) is mounted on the tester 1. The probe card 3 includes a plurality of probes (test needles). The prober 2 brings the plurality of probes provided on the probe card 3 into contact with pads of the plurality of semiconductor circuits formed on the wafer W. The prober 2 includes a tester moving device 2A, a stage device 2B, and a wafer transfer device 2C.

The tester moving device 2A includes a moving mechanism (not illustrated) and moves the tester 1 between a standby position 1A and an inspection position 1B. The stage device 2B supports the wafer W and aligns the tester 1 positioned at the inspection position 1B with the wafer W. The stage device 2B is movable in a planar direction along a horizontal plane and in a vertical direction perpendicular to the horizontal plane, and is also rotatable in a θ direction around a vertical axis. The wafer transfer device 2C transfers the wafer W onto the stage device 2B.

When the inspection is performed, the stage device 2B moves the wafer W and brings pads of the plurality of semiconductor circuits formed on the wafer W into contact with distal end parts of the plurality of probes provided on the tester 1 positioned at the inspection position 1B. In this state, the tester 1 inputs test signals simultaneously to the respective semiconductor circuits via the plurality of probes, and inspects the semiconductor circuits by receiving output signals from the respective semiconductor circuits.

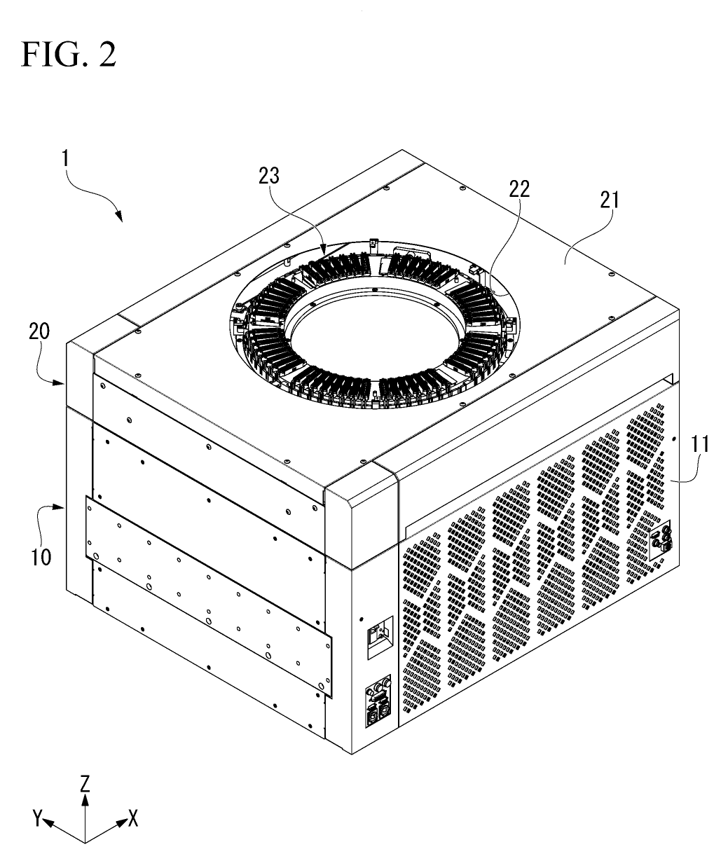

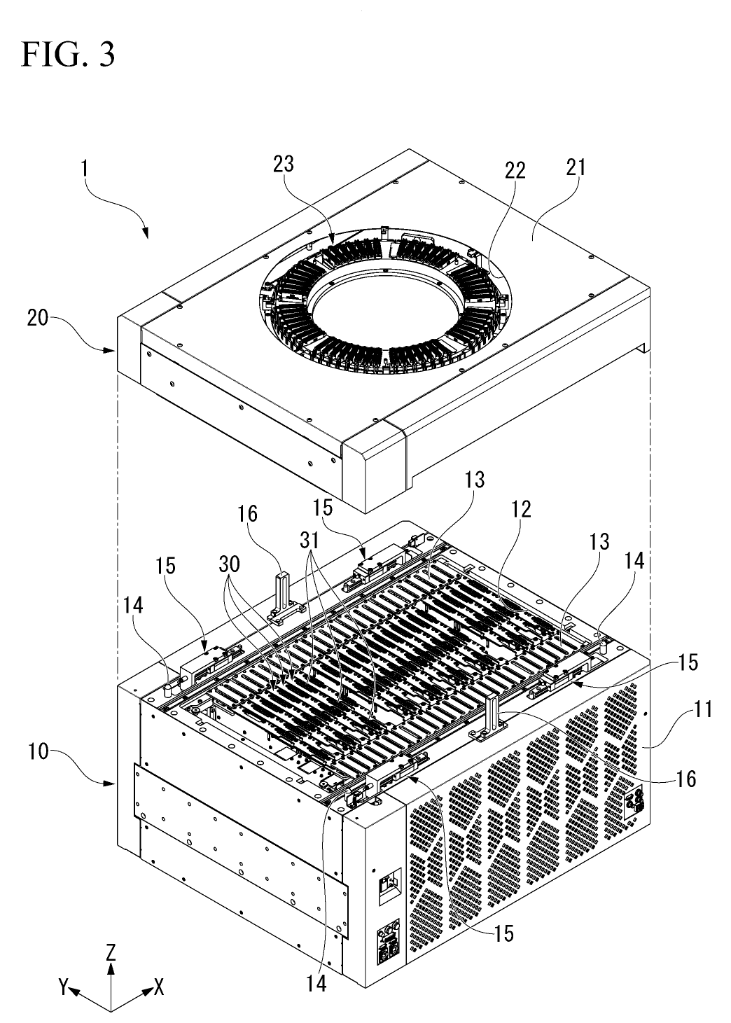

FIG. 2 is a perspective view of the tester 1 according to the first embodiment. FIG. 3 is an exploded perspective view of the tester 1 according to the first embodiment.

As illustrated in FIG. 2, the tester 1 includes a main body unit 10 and a performance board unit 20 (signal transmission unit). The tester 1 is formed in a rectangular box shape as a whole. The main body unit 10 houses a plurality of board units 30 (see FIG. 3) and power supply units (not illustrated) that supply power to the plurality of board units 30.

Further, in the following description, an XYZ orthogonal coordinate system is set, and positional relationships of respective members may be described with reference to the XYZ orthogonal coordinate system. An X-axis direction is a first linear direction along a horizontal plane, a Y-axis direction is a second linear direction perpendicular to the first linear direction on the horizontal plane, and a Z-axis direction is a vertical direction. Further, in the present embodiment, for convenience of explanation, the main body unit 10 is described as being disposed on a lower side (−Z side), and the performance board unit 20 side as being disposed on an upper side (+Z side), but this positional relationship can be changed depending on an orientation or posture of the tester 1.

As illustrated in FIG. 2, the performance board unit 20 includes a unit cover 21 in which an opening 22 is formed. The opening 22 is formed at a center of an upper surface of the unit cover 21. The opening 22 is formed in a circular shape in a plan view from the Z-axis direction. From the opening 22, a device mounting portion 23 on which the probe card 3 (see FIG. 1) can be mounted is exposed. The performance board unit 20 is detachably attached to an upper part of the main body unit 10.

As illustrated in FIG. 3, the main body unit 10 includes a rectangular box-shaped housing 11 that opens upward. An accommodating portion 12 that is open upward and accommodates the plurality of board units 30 is formed inside the housing 11. The plurality of board units 30 are accommodated in the accommodating portion 12 with gaps between them in the X-axis direction. The plurality of board units 30 generate test signals to be input to the plurality of semiconductor circuits formed on the wafer W, and receive and inspect output signals from the respective semiconductor circuits. The plurality of board units 30 can be increased or decreased in number, or replaced, in accordance with specifications of the semiconductor circuits formed on the wafer W.

A plurality of (two or three) first connectors 31 are provided on an upper part of each of the plurality of board units 30. The plurality of first connectors 31 are connected to a lower surface of the performance board unit 20. A board holder 13 that protrudes horizontally toward the accommodating portion 12 and restricts upward removal of the plurality of board units 30 is detachably attached to an upper end opening edge of the housing 11.

Also, a positioning pin 14 for positioning the performance board unit 20, a clamp device 15 for clamping the performance board unit 20, and a lock bracket 16 for locking the performance board unit 20 are provided at the upper end opening edge of the housing 11. The positioning pin 14 is provided at positions corresponding to three of four corner portions of the housing 11 in a plan view. Thereby, the performance board unit 20 can be prevented from being attached to the main body unit 10 in an incorrect orientation.

A total of four clamp devices 15 are provided, two on each of two sides of the upper end opening edge of the housing 11 extending in the X-axis direction. Of the four clamp devices 15, three cause clamp pins to advance and retract in the X-axis direction toward the positioning pins 14. The remaining one of the clamp devices 15 causes a clamp pin to advance and retract in the X-axis direction toward a corner portion of the housing 11 in which no positioning pin 14 is provided. The clamp device 15 is electrically driven and can be switched between a clamped state and an unclamped state with the performance board unit 20. A pair of lock brackets 16, each having a long hole extending in the Z-axis direction, are provided with the accommodating portion 12 interposed therebetween in the Y-axis direction.

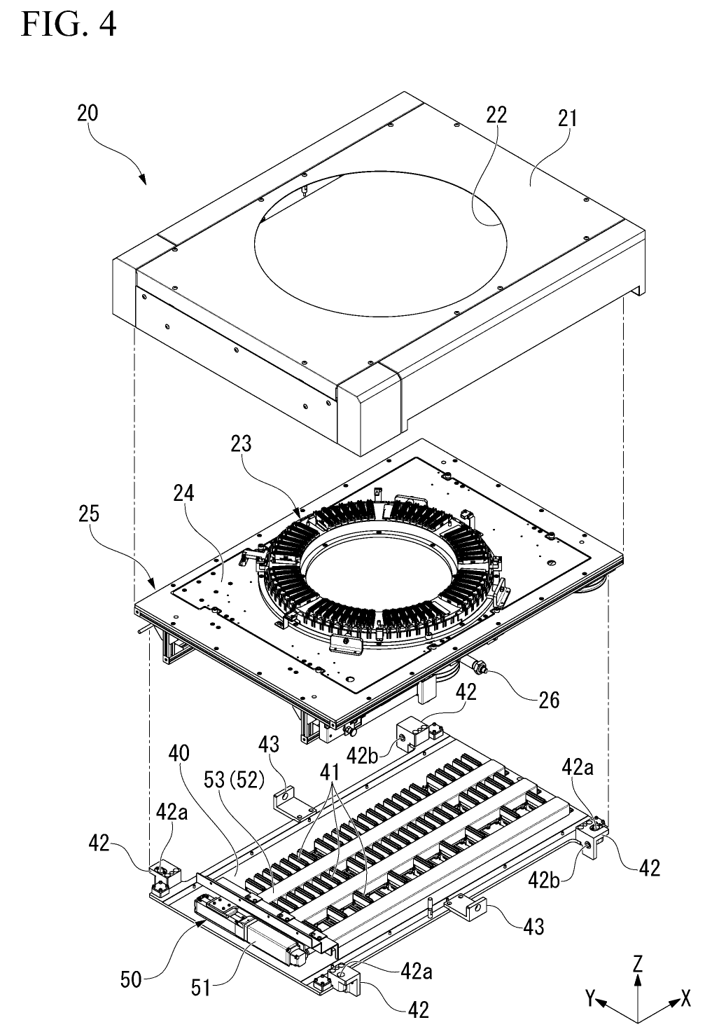

FIG. 4 is an exploded perspective view of the performance board unit 20 according to the first embodiment. As illustrated in FIG. 4, the performance board unit 20 includes a performance board 24 on which the device mounting portion 23 is provided. The performance board 24 is interposed between the probe card 3 (see FIG. 1) and the plurality of board units 30 (see FIG. 3), and transmits signals required for testing.

The device mounting portion 23 is provided on an upper surface of the performance board 24. A lock plunger 26 that can be fitted into the lock bracket 16 (see FIG. 3) is provided on a lower surface of the performance board 24. A pair of lock plungers 26 are provided in correspondence with the lock brackets 16. The lock plunger 26 is electrically driven and can switch between an engaged state and a disengaged state with respect to the lock bracket 16. The performance board 24 is attached to an underbase unit 40 via a frame unit 25.

The underbase unit 40 forms a lower surface of the performance board unit 20. A plurality of second connectors 41 are provided in the underbase unit 40. The plurality of second connectors 41 are provided in a number and disposition corresponding to the plurality of first connectors 31 illustrated in FIG. 3. The plurality of second connectors 41 are connected to the plurality of first connectors 31 in the Z-axis direction.

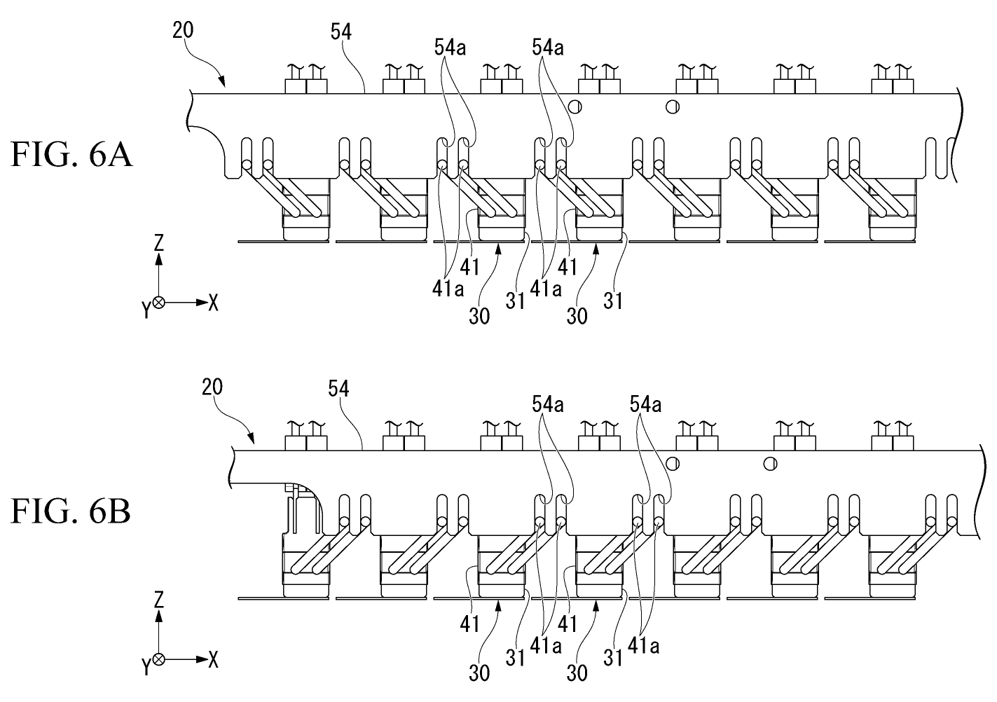

The first connector 31 and the second connector 41 are, for example, a zero insertion force (ZIF) connector. A lock lever 41a (see FIGS. 6A and 6B, which will be described later) is provided in the second connector 41. The second connector 41 can be switched, by operating the lock lever 41a, between a fixed state in which it is fixed to the first connector 31 and a released state in which the fixation to the first connector 31 is released. Further, as long as the fixed state and the released state can be switched by moving the lock lever 41a, the first connector 31 and the second connector 41 need not be ZIF connectors.

Returning to FIG. 4, the underbase unit 40 is formed in a rectangular plate shape in a plan view. An engagement piece 42 is attached to each of four corner portions of the underbase unit 40. The engagement piece 42, corresponding to the configuration on the main body unit 10, has a positioning hole 42a into which the positioning pin 14 can be inserted in the Z-axis direction, and a clamp hole 42b into which the clamp pin of the clamp device 15 can be inserted in the X-axis direction.

Mount pieces 43 for mounting the lock plungers 26 are attached at central portions of two sides of the underbase unit 40 extending in the X-axis direction. A unit attachment/detachment mechanism 50 is provided on an upper surface of the underbase unit 40. The unit attachment/detachment mechanism 50 includes a motor unit 51 and a lock lever interlocking mechanism 52. The lock lever interlocking mechanism 52 is covered by a cover member 53.

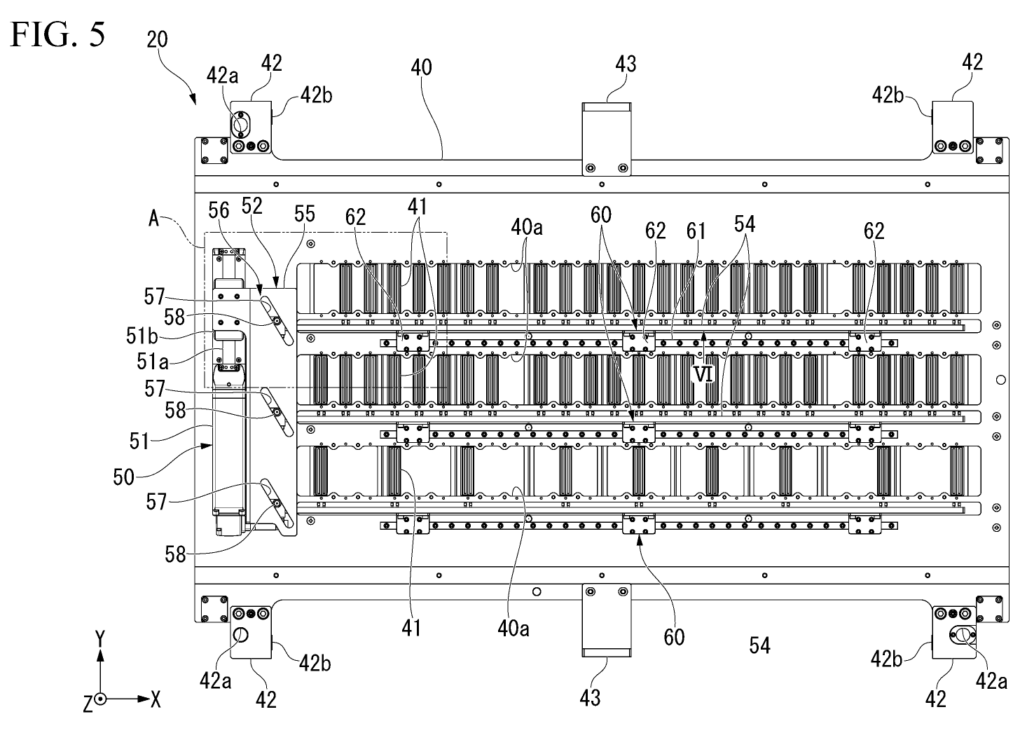

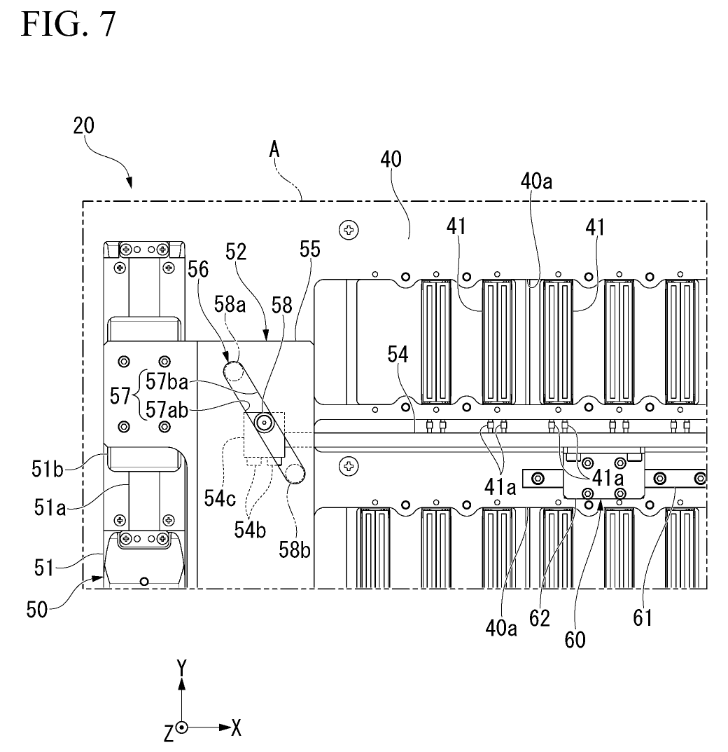

FIG. 5 is a plan view of the underbase unit 40 according to the first embodiment with the cover member 53 removed. FIGS. 6A and 6B is a view along the arrow VI illustrated in FIG. 5. FIG. 7 is an enlarged view of region A illustrated in FIG. 5.

As illustrated in FIG. 5, a plurality of (three) attachment holes 40a are formed in the underbase unit 40. The plurality of second connectors 41 are attached to the plurality of attachment holes 40a. The plurality of attachment holes 40a extend parallel to the X-axis direction at intervals in the Y-axis direction. The plurality of second connectors 41 form a row in the X-axis direction by being attached to the respective attachment holes 40a.

The motor unit 51 is disposed on the upper surface of the underbase unit 40 on a −X side of the plurality of attachment holes 40a. The motor unit 51 includes a ball screw 51a extending in the Y-axis direction, and a nut 51b that moves in the Y-axis direction along the ball screw 51a as the ball screw 51a rotates.

The lock lever interlocking mechanism 52 includes a plurality of (three) engagement members 54 provided to be movable in the X-axis direction (first linear direction) in a plan view, a moving member 55 provided to be movable in the Y-axis direction (second linear direction) that is orthogonal to the X-axis direction in a plan view, and a motion conversion mechanism 56 converting movement of the moving member 55 in the Y-axis direction into movement of the engagement member 54 in the X-axis direction.

As illustrated in FIGS. 6A and 6B, the engagement member 54 has a comb-tooth shape and includes a plurality of engagement grooves 54a that engage with a plurality of lock levers 41a. The plurality of engagement grooves 54a are open downward. As illustrated in FIG. 5, the engagement member 54 is disposed on the −Y side of the attachment hole 40a, extends linearly in the X-axis direction in which the second connectors 41 form a row, and engages with the lock lever 41a of each second connector 41. The engagement member 54 is connected to a linear guide 60.

The linear guide 60 includes a rail 61 extending in the X-axis direction and a plurality of slide blocks 62 that move along the rail 61. The engagement member 54 is attached to the plurality of slide blocks 62 and is movable in the X-axis direction. The engagement member 54 moves in the X-axis direction to move the lock lever 41a between a fixed position (see FIG. 6B) in which the plurality of second connectors 41 and the plurality of first connectors 31 are fixed and a released position (see FIG. 6A) in which the fixation between the plurality of second connectors 41 and the plurality of first connectors 31 is released.

As illustrated in FIG. 5, the moving member 55 is attached to the nut 51b of the motor unit 51 and is movable in the Y-axis direction. The moving member 55 is formed in a plate shape that is long in the Y-axis direction in a plan view. The motion conversion mechanism 56 includes a long hole 57 provided in the moving member 55 and extending in an oblique direction intersecting the X-axis direction and the Y-axis direction in a plan view, and a cam follower 58 provided in the engagement member 54 and movable along an inner wall of the long hole 57.

Three long holes 57 are formed corresponding to the three engagement members 54. The three long holes 57 extend parallel to each other in an oblique direction that is inclined toward the −Y side as proceeding toward the +X side in a plan view. The cam follower 58 is attached to an end part of each engagement member 54 on the −X side. The cam follower 58 includes a wheel portion that is rotatable around a shaft extending in the Z-axis direction.

As illustrated in FIG. 7, the cam follower 58 is attached to the end part of the engagement member 54 on the −X side via an attachment piece 54c. The attachment piece 54c has an inverted L-shape and is fixed to a surface of the engagement member 54 facing the Y-axis direction with a bolt 54b or the like. An outer diameter of the cam follower 58 is slightly smaller than a width of the long hole 57 and is capable of rolling along a first inner wall surface 57ba or a second inner wall surface 57ab of the long hole 57.

For example, when the moving member 55 moves to the −Y side, the cam follower 58 rolls along the first inner wall surface 57ba and moves to one end part 58a on the −X side of the long hole 57. When the cam follower 58 moves to the one end part 58a of the long hole 57, the engagement member 54 moves to the −X side together with the cam follower 58, and as a result, the lock lever 41a moves to the released position as illustrated in FIG. 6A.

Also, when the moving member 55 moves to the +Y side, the cam follower 58 rolls along the second inner wall surface 57ab facing the first inner wall surface 57ba and moves to the other end part 58b on the +X side of the long hole 57. When the cam follower 58 moves to the other end part 58b of the long hole 57, the engagement member 54 moves to the +X side together with the cam follower 58, and as a result, the lock lever 41a moves to the fixed position as illustrated in FIG. 6B.

Next, customization work of the tester 1 configured as described above (attachment/detachment work of the performance board unit 20) will be described.

In order to remove the performance board unit 20 from the main body unit 10, first, connector connections between the performance board unit 20 and the board units 30 are released. Specifically, the motor unit 51 illustrated in FIG. 5 is driven to move the moving member 55 to the −Y side. When the moving member 55 moves to the −Y side, the cam follower 58 moves to the −X side along the long hole 57. When the cam follower 58 moves to the −X side, the engagement member 54 moves to the −X side together with the cam follower 58, and as illustrated in FIG. 6A, the lock lever 41a engaged with the engagement member 54 moves (rotates) to the released position. Thereby, the fixation between the first connector 31 and the second connector 41 is released.

After the fixation between the first connector 31 and the second connector 41 is released, an electric signal is sent to the clamp device 15 (see FIG. 3) and the lock plunger 26 (see FIG. 4) to release the clamping and locking between the main body unit 10 and the performance board unit 20. Next, as illustrated in FIG. 3, the performance board unit 20 can be removed from the main body unit 10 by pulling the performance board unit 20 upward. When the performance board unit 20 is removed, the accommodating portion 12 of the main body unit 10 is opened, and the board units 30 can be easily replaced according to specifications of the semiconductor circuits formed on the wafer W. Also, the performance board unit 20 can also be replaced.

When the performance board unit 20 is replaced, or when the same performance board unit 20 is reattached to the main body unit 10, the attachment can be easily performed by performing the above-described steps in reverse order. Further, after attaching the performance board unit 20 to the main body unit 10, when the performance board unit 20 and the board units 30 are connected with connectors, the motor unit 51 illustrated in FIG. 5 is driven to move the moving member 55 to the +Y side. When the moving member 55 moves to the +Y side, the cam follower 58 moves to the +X side along the long hole 57. When the cam follower 58 moves to the +X side, the engagement member 54 moves to the +X side together with the cam follower 58, and the lock lever 41a engaged with the engagement member 54 moves (rotates) to the fixed position as illustrated in FIG. 6B. Thereby, the first connector 31 and the second connector 41 can be fixed together.

As described above, the tester 1 according to the present embodiment includes the performance board unit 20 on which the probe card 3 for testing a semiconductor circuit is mounted, the plurality of board units 30 electrically connected to the probe card 3 via the performance board unit 20, and the main body unit 10 having the accommodating portion 12 in which the plurality of board units 30 are accommodated, in which the performance board unit 20 is detachably attached to the main body unit 10 with the opening of the accommodating portion 12 closed. According to this configuration, when the performance board unit 20 is removed from the main body unit 10, the accommodating portion 12 is opened, and the board unit 30 can be replaced or the performance board unit 20 can be exchanged according to specifications of the semiconductor circuits formed on the wafer W. Therefore, it is possible to provide the compact tester 1 with high customizability.

Also, in the present embodiment, the tester 1 includes the plurality of first connectors 31 provided in the plurality of board units 30, the plurality of second connectors 41 provided in the performance board unit 20 and connected to the plurality of first connectors 31, the plurality of lock levers 41a provided in the plurality of second connectors 41 and movable between a fixed position in which the plurality of second connectors 41 and the plurality of first connectors 31 are fixed and a released position in which the fixation between the plurality of second connectors 41 and the plurality of first connectors 31 is released, and the lock lever interlocking mechanism 52 provided in the performance board unit 20 and moving the plurality of lock levers 41a between the fixed position and the released position. According to this configuration, connector connection and connector disconnection when the performance board unit 20 is attached to or detached from the main body unit 10 can be performed within a short period of time.

Also, in the present embodiment, the lock lever interlocking mechanism 52 includes the plurality of engagement members 54 provided to be movable in the X-axis direction (first linear direction) in a plan view and engaging with the plurality of lock levers 41a, the moving member 55 provided to be movable in the Y-axis direction (second linear direction) that is orthogonal to the X-axis direction in a plan view, and the motion conversion mechanism 56 converting movement of the moving member 55 in the Y-axis direction into movement of the engagement member 54 in the X-axis direction. According to this configuration, when linear movement in the X-axis direction is interlocked with linear movement in the Y-axis direction, the lock levers 41a of the plurality of second connectors 41 provided at high density in the performance board unit 20 can be moved in a space-saving manner.

Also, in the present embodiment, the motion conversion mechanism 56 includes the long hole 57 provided in the moving member 55 and extending in an oblique direction intersecting the X-axis direction and the Y-axis direction in a plan view, and the cam follower 58 provided in the engagement member 54 and movable along an inner wall of the long hole 57. According to this configuration, movement of the moving member 55 in the Y-axis direction can be converted into movement of the engagement member 54 in the X-axis direction with a simple structure.

### Second embodiment

Next, a second embodiment of the present invention will be described. In the following description, components the same as or equivalent to those of the above-described embodiment will be denoted by the same reference signs, and description thereof will be simplified or omitted.

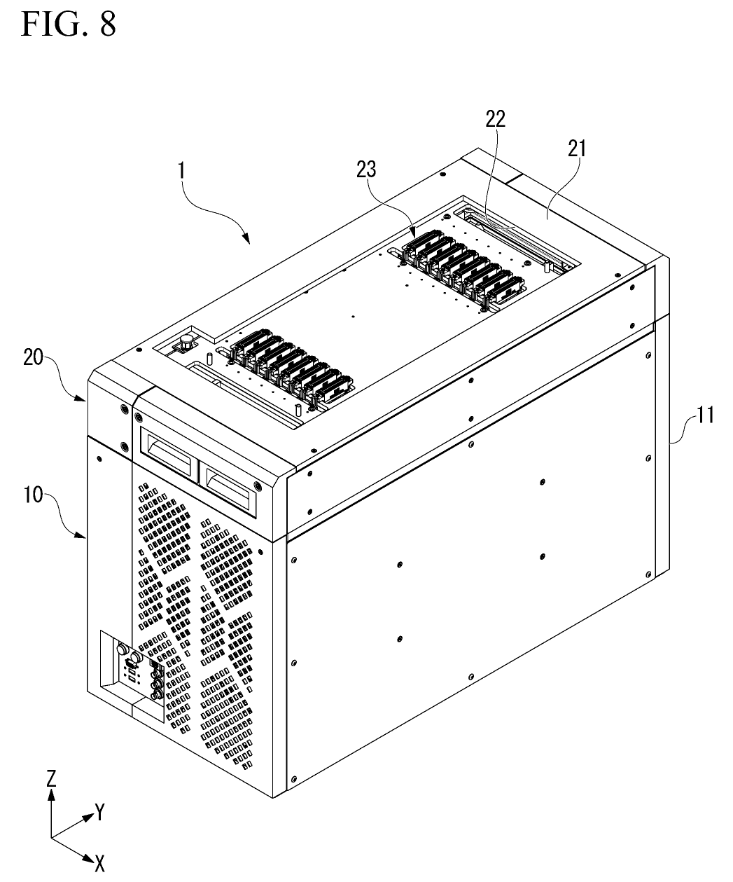

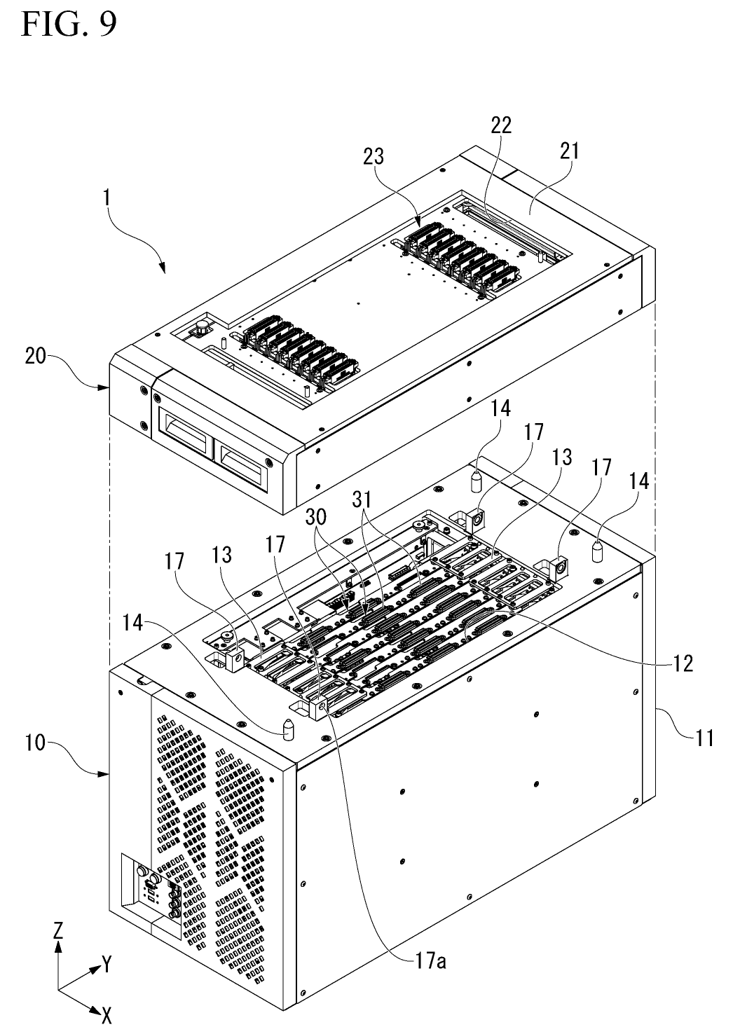

FIG. 8 is a perspective view of a tester 1 according to the second embodiment. FIG. 9 is an exploded perspective view of the tester 1 according to the second embodiment.

As illustrated in FIG. 8, the tester 1 of the second embodiment is formed in a rectangular shape extending in a Y-axis direction in a plan view. As illustrated in FIG. 9, in the tester 1, the number of board units 30 that can be accommodated in a main body unit 10 is smaller than the number of those accommodated in the main body unit 10 of the first embodiment illustrated in FIG. 3. The tester 1 of the second embodiment is used, for example, as a handler that dices semiconductor circuits from the wafer W into chips, packages them, and then inspects them by placing them on a test socket (device under test) (not illustrated).

As illustrated in FIG. 8, a device mounting portion 23 having a rectangular shape in a plan view and on which a test socket (not illustrated) can be mounted is provided on a performance board unit 20. Also, as illustrated in FIG. 9, the main body unit 10 includes a rectangular box-shaped housing 11 that opens upward. An accommodating portion 12 that is open upward and accommodates a plurality of board units 30 is formed inside the housing 11.

At an upper end opening edge of the housing 11, a clamp pin insertion piece 17 is provided instead of the clamp device 15 illustrated in FIG. 3 described above. A total of four clamp pin insertion pieces 17 are provided, two on each of two sides of the upper end opening edge of the housing 11 extending in an X-axis direction. A clamp hole 17a penetrating in the X-axis direction is formed in the clamp pin insertion piece 17.

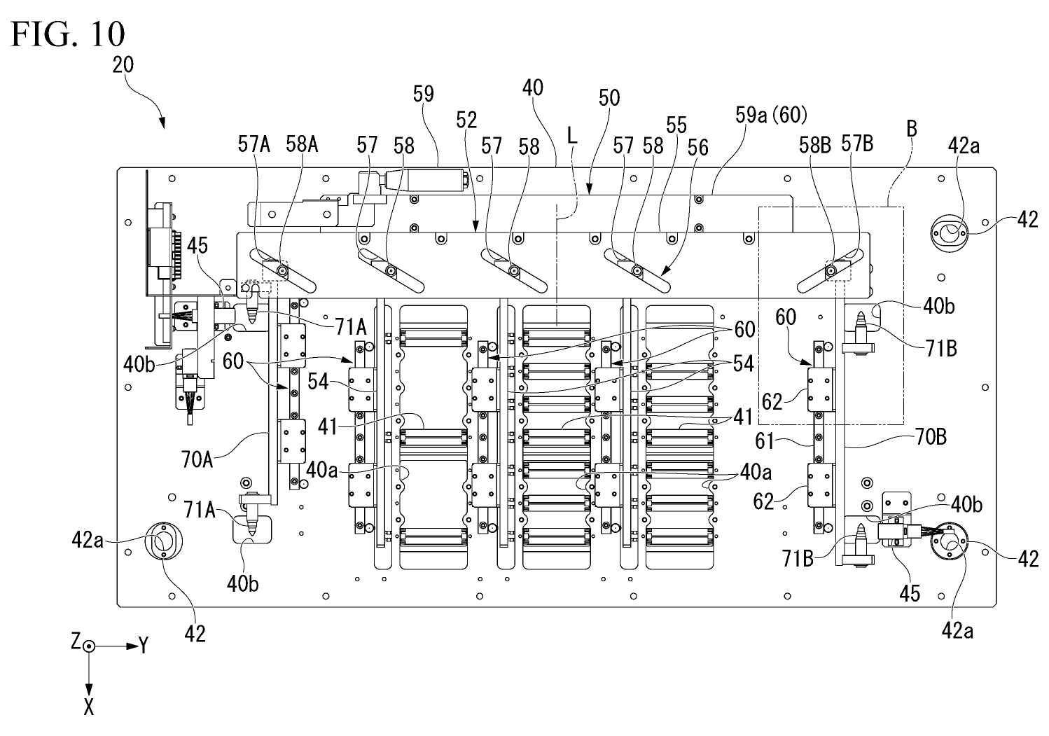

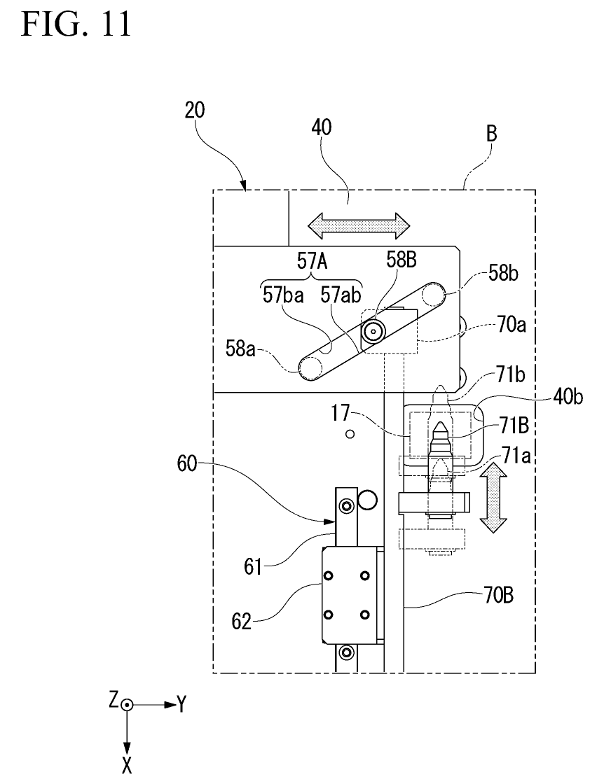

FIG. 10 is a plan view of an underbase unit 40 according to the second embodiment. FIG. 11 is an enlarged view of region B illustrated in FIG. 10.

As illustrated in FIG. 10, a plurality of attachment holes 40a to which a plurality of second connectors 41 are attached are formed in the underbase unit 40. The plurality of (three) attachment holes 40a extend parallel to the X-axis direction at intervals in the Y-axis direction. The plurality of second connectors 41 form a row in the X-axis direction by being attached to the respective attachment holes 40a.

A plurality of insertion holes 40b into which the plurality of clamp pin insertion pieces 17 are inserted in the Z-axis direction are formed in the underbase unit 40. The plurality of insertion holes 40b are provided in a number and disposition corresponding to the plurality of clamp pin insertion pieces 17 illustrated in FIG. 9. Of the plurality of insertion holes 40b, an optical sensor 45 for checking a clamped state is provided near one of the two insertion holes 40b disposed on the −Y side and near one of the two insertion holes 40b disposed on the +Y side.

The unit attachment/detachment mechanism 50 includes a lever unit 59 that can be manually operated and a lock lever interlocking mechanism 52. The lever unit 59 can be accessed by, for example, removing a part of a unit cover 21 of the performance board unit 20. The lever unit 59 is disposed on the −X side of the plurality of attachment holes 40a on an upper surface of the underbase unit 40.

The lever unit 59 includes a moving plate 59a that is movable in the Y-axis direction by a lever operation thereof around an axis extending in the X-axis direction. A linear guide 60 is attached to a lower surface of the moving plate 59a and is movable in the Y-axis direction. The moving plate 59a is connected to a moving member 55 of the lock lever interlocking mechanism 52. According to this configuration, the moving member 55 can be moved in the Y-axis direction by the lever operation of the lever unit 59. Further, also in the second embodiment, a motor unit 51 may be provided instead of the lever unit 59 to make it electrically driven.

A first clamp member 70A and a second clamp member 70B are connected to the moving member 55 via a motion conversion mechanism 56. The first clamp member 70A is disposed on the −Y side of the underbase unit 40. A pair of first clamp pins 71A, with their distal ends directed toward the +X side, are attached to the first clamp member 70A. The first clamp pins 71A are disposed at positions corresponding to the insertion holes 40b. The first clamp member 70A is connected to the linear guide 60 and is movable in the X-axis direction.

The second clamp member 70B is disposed on the +Y side of the underbase unit 40. A pair of second clamp pins 71B, with their distal ends directed toward the −X side, are attached to the second clamp member 70B. The second clamp pins 71B are disposed at positions corresponding to the insertion holes 40b. The second clamp member 70B is connected to the linear guide 60 and is movable in the X-axis direction.

The motion conversion mechanism 56 includes a first long hole 57A provided in the moving member 55 and extending parallel to the long hole 57 described above, and a first cam follower 58A provided in the first clamp member 70A and movable along an inner wall of the first long hole 57A. That is, the first clamp member 70A moves in the X-axis direction together with the engagement member 54 described above. The first long hole 57A is formed at end part of the moving member 55 on the −Y side.

When the engagement member 54 moves to the +X side, the first clamp member 70A also moves to the +X side, the second connector 41 is brought into a fixed state, and the first clamp pin 71A is inserted into the clamp pin insertion piece 17 to be in a clamped state. When the engagement member 54 moves to the −X side, the first clamp member 70A also moves to the −X side, the second connector 41 is brought into a released state, and the first clamp pin 71A is removed from the clamp pin insertion piece 17 to be in an unclamped state.

The motion conversion mechanism 56 includes a second long hole 57B provided in the moving member 55 and oriented in a direction line-symmetrical with the first long hole 57A with respect to a symmetry axis L extending in the X-axis direction in a plan view, and a second cam follower 58B provided in the second clamp member 70B and movable along an inner wall of the second long hole 57B. That is, the second clamp member 70B moves in a direction opposite to that of the engagement member 54 and the first clamp member 70A described above. The second long hole 57B is formed at an end part of the moving member 55 on the +Y side. Further, as long as the second long hole 57B is oriented in a direction line-symmetrical with the first long hole 57A, it does not need to be disposed at the same distance from the symmetry axis L as the first long hole 57A.

As illustrated in FIG. 11, the second cam follower 58B is attached to an end part on the −X side of the second clamp member 70B via an attachment piece 70a. An outer diameter of the second cam follower 58B is slightly smaller than a width of the second long hole 57B and is capable of rolling along a first inner wall surface 57ba or a second inner wall surface 57ab of the second long hole 57B.

For example, when the moving member 55 moves to the +Y side, the second cam follower 58B rolls along the first inner wall surface 57ba and moves to one end part 58a on the +X side of the second long hole 57B. When the second cam follower 58B moves to the one end part 58a of the second long hole 57B, the second clamp member 70B moves to the +X side together with the second cam follower 58B, and as a result, the second clamp pin 71B moves to an unclamped position 71a at which it is removed from the clamp pin insertion piece 17 to be in an unclamped state.

Also, when the moving member 55 moves to the −Y side, the second cam follower 58B rolls along the second inner wall surface 57ab facing the first inner wall surface 57ba, and moves to the other end part 58b on the −X side of the second long hole 57B. When the second cam follower 58B moves to the other end part 58b of the second long hole 57B, the second clamp member 70B moves to the -X side together with the second cam follower 58B, and as a result, the second clamp pin 71B moves to a clamped position 71b at which it is inserted into the clamp pin insertion piece 17 to be in a clamped state.

As described above, according to the second embodiment, the tester 1 includes the first clamp member 70A and the second clamp member 70B provided in the performance board unit 20 and moving in the X-axis direction in a plan view to switch between a clamped state in which the performance board unit 20 is non-detachably attached to the main body unit 10 and an unclamped state in which the performance board unit 20 is detachably attached to the main body unit 10, and the motion conversion mechanism 56 includes the first long hole 57A provided in the moving member 55 and extending parallel to the long hole 57, the first cam follower 58A provided in the first clamp member 70A and movable along an inner wall of the first long hole 57A, the second long hole 57B provided in the moving member 55 and oriented in a direction line-symmetrical with the first long hole 57A with respect to the symmetry axis L extending in the X-axis direction in a plan view, and the second cam follower 58B provided in the second clamp member 70B and movable along an inner wall of the second long hole 57B. According to this configuration, switching between the fixed state and the released state of the second connector 41 can be interlocked with switching between the clamped state and the unclamped state of the first clamp member 70A and the second clamp member 70B. Also, since the first clamp member 70A and the second clamp member 70B move in directions opposite to each other in the X-axis direction, clamp loosening of the performance board unit 20 due to sliding in the X-axis direction can be restricted.

While preferred embodiments of the present invention have been described and illustrated, it should be understood that they are exemplary of the present invention and are not to be considered as limiting. Additions, omissions, substitutions, and other modifications can be made without departing from the scope of the present invention. Accordingly, the present invention is not to be considered as being limited by the foregoing description and is only limited by the scope of the claims.

For example, in the above-described embodiment, three engagement members 54 are provided, but if the second connectors 41 are provided in a single row, the number of the engagement members 54 may be one.

In addition, the components in the above-described embodiments can be appropriately replaced with well-known components within a range not departing from the spirit of the present invention, and the above-described embodiments and modified examples may be appropriately combined.

What is claimed is:

1. A semiconductor testing device comprising:
a signal transmission unit on which a device under test for testing a semiconductor circuit is mounted;
a plurality of board units electrically connected to the device under test via the signal transmission unit; and
a main body unit having an accommodating portion in which the plurality of board units are accommodated, wherein
the signal transmission unit is detachably attached to the main body unit with an opening of the accommodating portion closed.

2. The semiconductor testing device according to claim 1, comprising:
a plurality of first connectors provided in the plurality of board units;
a plurality of second connectors provided in the signal transmission unit and connected to the plurality of first connectors;
a plurality of lock levers provided in the plurality of second connectors and movable between a fixed position in which the plurality of second connectors and the plurality of first connectors are fixed and a released position in which a fixation between the plurality of second connectors and the plurality of first connectors is released; and
a lock lever interlocking mechanism provided in the signal transmission unit and moving the plurality of lock levers between the fixed position and the released position.

3. The semiconductor testing device according to claim 2, wherein the lock lever interlocking mechanism includes:
one or more engagement members provided to be movable in a first linear direction in a plan view and engaging with the plurality of lock levers;
a moving member provided to be movable in a second linear direction that is orthogonal to the first linear direction in a plan view; and
a motion conversion mechanism converting movement of the moving member in the second linear direction into movement of the engagement member in the first linear direction.

4. The semiconductor testing device according to claim 3, wherein the motion conversion mechanism includes:
a long hole provided in the moving member and extending in an oblique direction intersecting the first linear direction and the second linear direction in a plan view; and
a cam follower provided in the engagement member and movable along an inner wall of the long hole.

5. The semiconductor testing device according to claim 4, further comprising:
a first clamp member and a second clamp member provided in the signal transmission unit and moving in the first linear direction in a plan view to switch between a clamped state in which the signal transmission unit is non-detachably attached to the main body unit and an unclamped state in which the signal transmission unit is detachably attached to the main body unit, wherein
the motion conversion mechanism includes:
a first long hole provided in the moving member and extending parallel to the long hole;
a first cam follower provided in the first clamp member and movable along an inner wall of the first long hole;
a second long hole provided in the moving member and oriented in a direction line-symmetrical with the first long hole with respect to a symmetry axis extending in the first linear direction in a plan view; and
a second cam follower provided in the second clamp member and movable along an inner wall of the second long hole.
